(19) United States
(12) Patent Application Publication
(10) Pub. No.: US 2013/0269765 A1
(43) Pub. Date: Oct. 17, 2013

(54) BIDIRECTIONAL COLOR EMBODIMENT THIN FILM SILICON SOLAR CELL

(71) Applicant: ELECTRONICS AND TELECOMMUNICATIONS RESEARCH IN, Daejeon (KR)

(72) Inventors: JungWook Lim, Daejeon (KR); Seong Hyun Lee, Busan (KR); Sun Jin Yun, Daejeon (KR); Da Jung Lee, Gyeongsangbuk-do (KR)

(73) Assignee: Electronics and Telecommunications Research Institute, Daejeon (KR)

(21) Appl. No.: 13/660,458

(22) Filed: Oct. 25, 2012

(30) Foreign Application Priority Data
Apr. 13, 2012 (KR) 10-2012-0038508

(51) Int. Cl. H01L 31/0232

(52) U.S. Cl. 136/256

(57) ABSTRACT

Provided is a thin film silicon solar cell. The thin film silicon solar cell includes a light absorbing layer, a front transparent electrode disposed on one surface of the light absorbing layer to emit light having a first color, and a rear transparent electrode disposed on the other surface of the light absorbing layer to emit light having a second color.

### CROSS-REFERENCE TO RELATED APPLICATIONS

This U.S. non-provisional patent application claims priority under 35 U.S.C. §119 of Korean Patent Application No. 10-2012-0038508, filed on Apr. 13, 2012, the entire contents of which are hereby incorporated by reference.

### BACKGROUND OF THE INVENTION

The present invention disclosed herein relates to a bidirectional color embodiment thin film silicon solar cell, and more particularly, to a bidirectional color embodiment thin film silicon solar cell which can independently embody colors on both side surfaces thereof.

Solar cells are photovoltaic energy conversion systems which convert solar energy emitted from the sun into electricity energy. Crystalline silicon solar cells occupy most of the solar cell markets. It is difficult to embody crystalline silicon solar cells in various shapes and materials. However, it is possible to embody thin film silicon solar cells in various shapes and materials. In addition, silicon materials used for manufacturing thin film silicon solar cells are nontoxic, rich, and stable.

Since the aesthetic of solar cells is a very important factor in future, securing of technologies for embodying various colors is required. Thus, transparent solar cells may be in increasing demand in building integrated photovoltaic (BPIV) markets and vehicle sunroof markets. In case of dye-sensitized solar cells, it is difficult to embody large scale solar cells and also secure stability and long life.

### SUMMARY OF THE INVENTION

The present invention provides a thin film silicon solar cell which can independently embody colors on both side surfaces thereof.

The present invention also provides a thin film silicon solar cell which can independently embody colors on both side surfaces thereof having improved optical efficiency.

The feature of the present invention is not limited to the aforesaid, but other features not described herein will be clearly understood by those skilled in the art from descriptions below.

Embodiments of the present invention provide a thin film silicon solar cell including: a light absorbing layer; a front transparent electrode disposed on one surface of the light absorbing layer to emit light having a first color; and a rear transparent electrode disposed on the other surface of the light absorbing layer to emit light having a second color.

In some embodiments, the light absorbing layer, the front transparent electrode, and the rear transparent electrode may have refractive indexes different from each other.

In other embodiments, the front transparent electrode and the rear transparent electrode may have the same thickness.

In still other embodiments, the front transparent electrode may have a thickness greater than that of the rear transparent electrode.

In even other embodiments, the front transparent electrode may have a thickness less than that of the rear transparent electrode.

In yet other embodiments, each of the front transparent electrode and the rear transparent electrode may have a thickness of about 50 nm to about 1,500 nm.

In further embodiments, each of the front transparent electrode and the rear transparent electrode may be formed of one of ITO, ZnO:Al, ZnO:Ga, and SnO₂:F.

In still further embodiments, the light absorbing layer may include one of an amorphous silicon layer, an amorphous silicon germanium layer, a micro crystalline silicon layer, and a micro crystalline silicon germanium layer.

In other embodiments of the present invention, thin film silicon solar cells include: a light absorbing layer; a front transparent electrode disposed on one surface of the light absorbing layer to emit light having a first color; a rear transparent electrode disposed on the other surface of the light absorbing layer to emit light having a second color a front substrate disposed on the front transparent electrode, the front substrate being spaced apart from the light absorbing layer; a rear substrate disposed on the rear transparent electrode, the rear substrate being spaced apart from the light absorbing layer; and a first color calibration thin film disposed between the front substrate and the front transparent electrode.

In some embodiments, thin film silicon solar cells may further include a second color calibration thin film between the rear substrate and the rear transparent electrode.

In other embodiments, each of the front substrate and the rear substrate may include a transparent substrate.

In still other embodiments, the first color calibration thin film may have a thickness of about 100 nm to about 1,000 nm.

In even other embodiments, the first color calibration thin film may be formed of an insulation material having a refractive index of about 1.4 to about 2.5.

In yet other embodiments, the insulation material may include one of Al2O3, TiO₂, AlTiO, and HfO₂.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIGS. 1 to 3 are cross-sectional views of a thin film silicon solar cell according to an embodiment of the present invention;

FIG. 4 is a graph illustrating reflectivity depending on a thickness of a transparent electrode in the thin film silicon solar cell according to an embodiment of the present invention;

FIGS. 5 and 6 are cross-sectional views of a thin film silicon solar cell according to another embodiment of the present invention; and

FIG. 7 is a graph illustrating reflectivity depending on whether a color calibration thin film exists in the thin film silicon solar cell according to another embodiment of the present invention.

### DETAILED DESCRIPTION OF PREFERRED EMBODIMENTS

Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims. In the drawings, the dimensions of layers and regions are exaggerated for clarity of illustration.

In the following description, the technical terms are used only for explain a specific exemplary embodiment while not limiting the present invention. The terms of a singular form may include plural forms unless referred to the contrary. The meaning of “include,” “comprise,” “including,” or “comprising,” specifies a property, a region, a fixed number, a step, a process, an element and/or a component but does not exclude other properties, regions, fixed numbers, steps, processes, elements and/or components.

Additionally, the embodiment in the detailed description will be described with sectional views as ideal exemplary views of the present invention. In the figures, the dimensions of layers and regions are exaggerated for clarity of illustration. Accordingly, shapes of the exemplary views may be modified according to manufacturing techniques and/or allowable errors. Therefore, the embodiments of the present invention are not limited to the specific shape illustrated in the exemplary views, but may include other shapes that may be created according to manufacturing processes. For example, an etched region illustrated or described as a rectangle will, typically, have rounded or curved features. Thus, the regions illustrated in the figures are schematic in nature and their shapes are not intended to illustrate the precise shape of a region of a device and are not intended to limit the scope of the present invention.

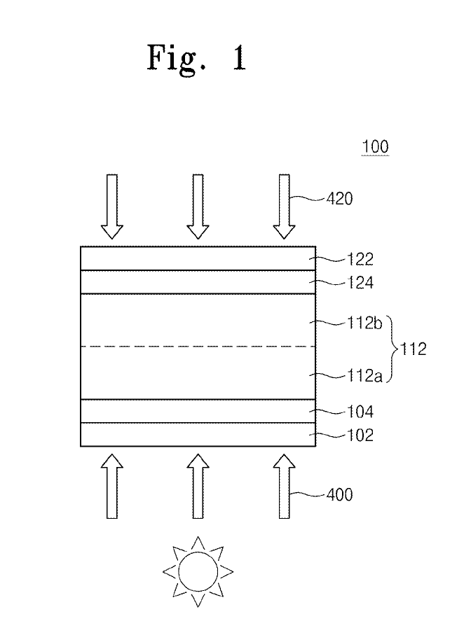

FIGS. 1 to 3 are cross-sectional views of a thin film silicon solar cell according to an embodiment of the present invention.

Referring to FIG. 1, a thin film silicon solar cell 100 includes a light absorbing layer 112.

A front transparent electrode 104 may be disposed on one surface of the light absorbing layer 112, and a front substrate 102 may be disposed on the front transparent electrode 104. A rear transparent electrode 124 may be disposed on the other surface of the light absorbing layer 112, and a rear substrate 122 may be disposed on the rear transparent electrode 124.

The front substrate 102 and the rear substrate 122 may be transparent glass substrates, respectively.

Each of the front substrate 102 and the rear substrate 122 may have a refractive index of about 1.5. First light 400 may be incident into the front substrate 102, and second light 420 may be incident into the rear substrate 122. The first light 400 may be solar light. The second light 420 may be light different from the solar light.

The front transparent electrode 104 and the rear transparent electrode 124 may be formed of transparent conductive materials, respectively. The front transparent electrode 104 and the rear transparent electrode 124 may be formed of, for example, one of ITO, ZnO:Al, ZnO:Ga, and SnO₂:F. Each of the front transparent electrode 104 and the rear transparent electrode 124 may have a refractive index of about 1.5 to about 2.0. Each of the front transparent electrode 104 and the rear transparent electrode 124 may have a thickness of about 50 nm to about 1,500 nm.

The light absorbing layer 122 may be a single layer and/or a multilayer. The light absorbing layer 112 may include at least one of an amorphous silicon layer, an amorphous silicon germanium layer, a micro crystalline silicon layer, and a micro crystalline silicon germanium layer. The light absorbing layer 112 may have a refractive index of about 3.5. The light absorbing layer 112 may include a first conductive layer 112a and a second conductive layer 112b. The first conductive layer 112a may be an n-type doped layer, and the second conductive layer 112b may be a p-type doped layer. For example, the first conductive layer 112a may be a layer doped with a group V element such as P, As, Sb, etc. For example, the second conductive layer 112b may be a layer doped with a group III element such as B, Ga, In, etc. Thus, a p-n junction may be formed between the first conductive layer 112a and the second conductive layer 112b. Electric fields may occur by the p-n junction. On the other hand, a layer in which impurities are undoped may be further provided between the first conductive layer 112a and the second conductive layer 112b.

The first light 400 incident into the front substrate 102 may transmit the front transparent electrode 104. The first light 400 transmitting the front transparent electrode 104 is absorbed into the light absorbing layer 112 to generate carriers (for example, electrons or holes). The carriers may be moved into the first conductive layer 112a and the second conductive layer 112b by the electric fields. For example, the electrons may be moved into the first conductive layer 112a, and the holes may be moved into the second conductive layer 112b. Thus, a current between the first conductive layer 112a and the second conductive layer 112b may be generated.

A portion of the first light 400 which is not absorbed into the light absorbing layer 112 may be reflected by an interface between the front transparent electrode 104 and the light absorbing layer 112. A portion of the first light 400 may be reflected by a refractive index difference between the front transparent electrode 104 and the light absorbing layer 112. The reflected first light 400 may vary in color according to a thickness of the front transparent electrode 104. That is, the front transparent electrode 104 may emit light having a color corresponding to a wavelength band of the reflected first light 400 according to a thickness of the front transparent electrode 104. A color of a front surface of the thin film silicon solar cell 100 may be determined through the first light 400 reflected by the interface between the front transparent electrode 104 and the light absorbing layer 112.

The second light 420 incident into the rear substrate 122 may transmit the rear transparent electrode 124. However, a portion of the second light 420 transmitting the rear transparent electrode 124 may be reflected by an interface between the rear transparent electrode 124 and the light absorbing layer 112. A portion of the second light 420 may be reflected by a refractive index difference between the rear transparent electrode 124 and the light absorbing layer 112. The reflected second light 420 may vary in color according to a thickness of the rear transparent electrode 124. That is, the rear transparent electrode 124 may emit light having a color corresponding to a wavelength band of the reflected second light 420 according to a thickness of the rear transparent electrode 124. Thus, a color of a rear surface of the thin film silicon solar cell 100 may be determined through the second light 420 reflected by the rear transparent electrode 124 and the light absorbing layer 112. According to the embodiment of FIG. 1, the first transparent electrode 104 and the rear transparent electrode 124 may have the same thickness. Thus, the same color may be embodied on both side surfaces of the thin film silicon solar cell 100.

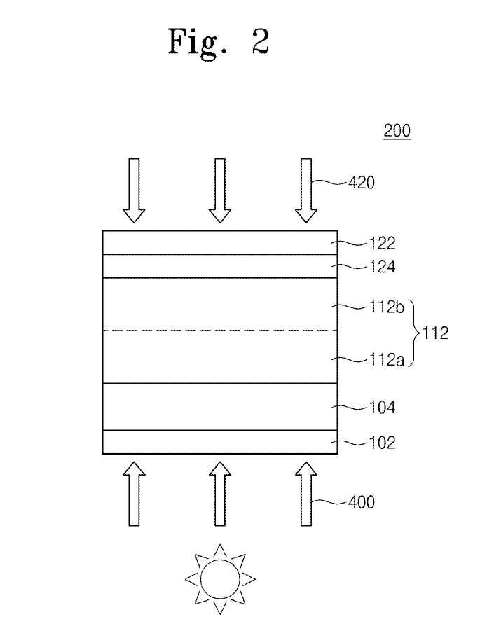

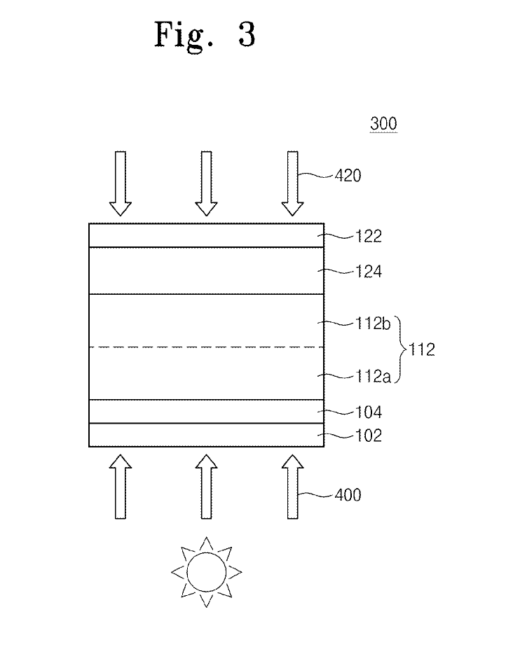

According to an embodiment of FIG. 2, the front transparent electrode 104 in a thin film silicon solar cell 200 may have a thickness greater than that of the rear transparent electrode 124. According to an embodiment of FIG. 3, the front transparent electrode 104 in a thin film silicon solar cell 300 may have a thickness less than that of the rear transparent electrode 124. In the embodiments of FIGS. 2 and 3, since the front transparent electrode 104 and the rear transparent electrode 124 have thicknesses different from each other, a wavelength band of light reflected by the interface between the front transparent electrode 104 and the light absorbing layer 112 and a wavelength band of light reflected by the interface between the rear transparent electrode 124 and the light absorbing layer 112 may be different from each other. Thus, colors different from each other may be embodied on both side surfaces of the thin film silicon solar cell 200, respectively.

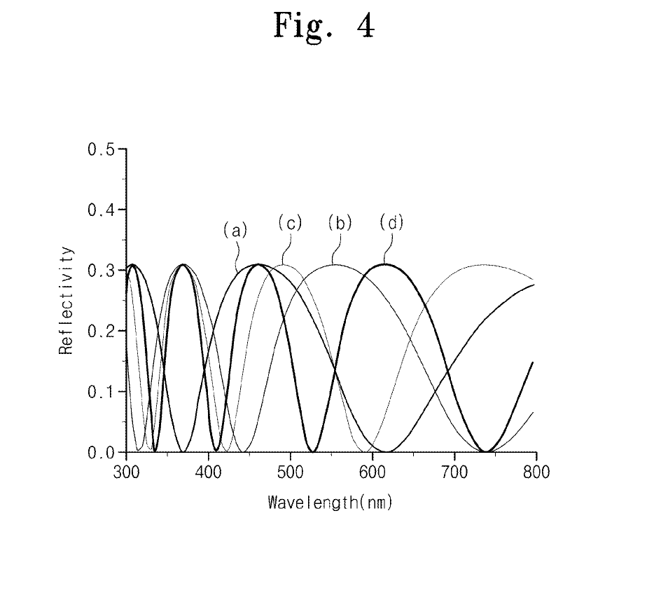

FIG. 4 is a graph illustrating reflectivity depending on a thickness of a transparent electrode in the thin film silicon solar cell according to an embodiment of the present invention.

Referring to FIG. 4, a wavelength band of reflected light depending on a thickness of a transparent electrode when light is incident into a solar cell is measured. For example, the transparent electrode may have one of thicknesses of about (a) 250 nm, about (b) 300 nm, about (c) 400 nm, and about (d) 500 nm. In detail, in a case where the transparent electrode has a thickness of about (a) 250 nm, reflectivity may be maximized in the vicinity of a wavelength band of about 450 nm corresponding to that of visible light, and the remnants of the transparent electrode may have low reflectivity. Thus, light having a blue color that is a color corresponding to a wavelength band of about 450 nm may be effectively reflected. That is, in the embodiments of FIGS. 1 to 3, in a case where the front transparent electrode 104 or the rear transparent electrode 124 has a thickness of about (a) 250 nm, the front transparent electrode 104 or the rear transparent electrode 124 may emit blue light.

In a case where the transparent electrode has a thickness of about (b) 300 nm, reflectivity may be maximized in the vicinity of wavelength bands of about 380 nm and about 550 nm corresponding to that of visible light, and the remnants of the transparent electrode may have low reflectivity. Thus, light having violet and green colors, which are colors corresponding to wavelength bands of about 350 nm and about 550 nm, respectively, may be effectively reflected. That is, in the embodiments of FIGS. 1 to 3, in a case where the front transparent electrode 104 or the rear transparent electrode 124 has a thickness of about (b) 300 nm, the front transparent electrode 104 or the rear transparent electrode 124 may emit light having a color in which the violet color and the green color are mixed.

In a case where the transparent electrode has a thickness of about (c) 400 nm, reflectivity may be maximized in the vicinity of wavelength bands of about 380 nm, about 550 nm, and about 730 nm corresponding to that of visible light, and the remnants of the transparent electrode may have low reflectivity. Thus, light having violet, green, and red colors, which are colors corresponding to wavelength bands of about 380 nm, about 550 nm, and about 730 nm, respectively, may be effectively reflected. That is, in the embodiments of FIGS. 1 to 3, in a case where the front transparent electrode 104 or the rear transparent electrode 124 has a thickness of about (c) 400 nm, the front transparent electrode 104 or the rear transparent electrode 124 may emit light having a color in which the violet color, the green color, and the red color are mixed.

In a case where the transparent electrode has a thickness of about (d) 500 nm, reflectivity may be maximized in the vicinity of wavelength bands of about 380 nm, about 450 nm, and about 620 nm corresponding to that of visible light, and the remnants of the transparent electrode may have low reflectivity. Thus, light having violet, blue, and orange colors, which are colors corresponding to wavelength bands of about 380 nm, about 450 nm, and about 620 nm, respectively, may be effectively reflected. That is, in the embodiments of FIGS. 1 to 3, in a case where the front transparent electrode 104 or the rear transparent electrode 124 has a thickness of about (d) 500 nm, the front transparent electrode 104 or the rear transparent electrode 124 may emit light having a color in which the violet color, the blue color, and the orange color are mixed.

As described above, since reflected light has wavelength bands different from each other according to thicknesses of the transparent electrode, the thin film silicon solar cell may independently embody colors on both side surfaces thereof. In detail, referring to FIGS. 1 to 4, when the front transparent electrode 104 and the rear transparent electrode 124 have the same thickness, the same color may be emitted from both side surfaces of the thin film silicon solar cell. For example, when each of the front transparent electrode 104 and the rear transparent electrode 124 has a thickness of about (a) 250 nm, the front transparent electrode 104 and the rear transparent electrode 124 may emit blue light.

On the other hand, referring to FIGS. 2 and 4, when the front transparent electrode 104 and the rear transparent electrode 124 have thicknesses different from each other, the thin film silicon solar cell may embody different colors on both side surfaces thereof. For example, the front transparent electrode 104 may have a thickness of about (a) 250 nm, and the rear transparent electrode 124 may have a thickness of about (b) 300 nm. Here, the front transparent electrode 104 may emit blue light, and the rear transparent electrode 124 may emit light having a color in which a violet color and a green color are mixed.

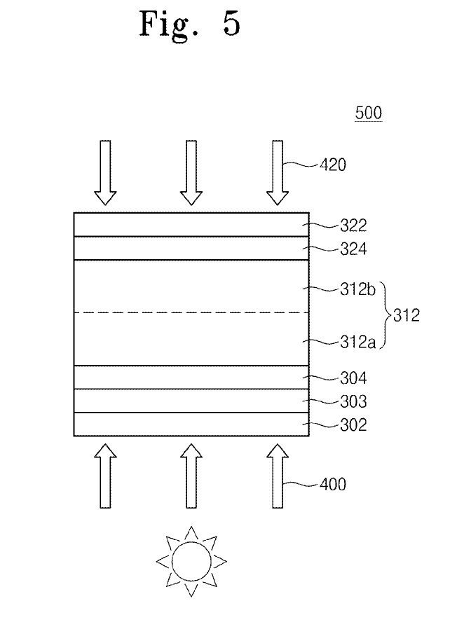

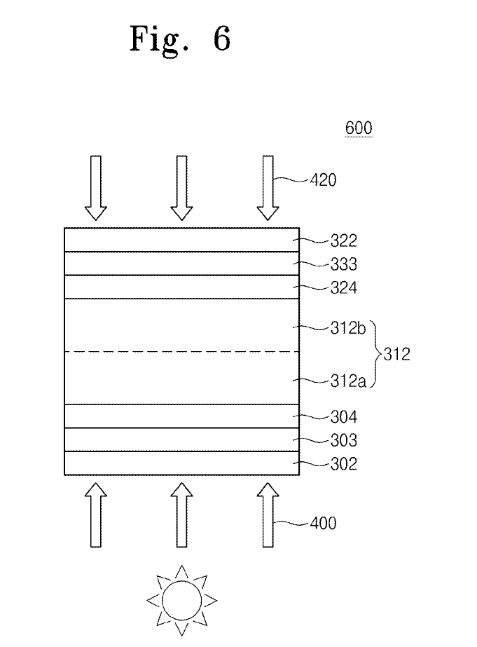

In the embodiments of FIGS. 1 to 3, although the front transparent electrode 104 and the rear transparent electrode 124 may be adjusted in thickness to independently embody colors on both side surfaces of the thin film silicon solar cell, an amount of first light 400 absorbed into the light absorbing layer 112 may vary according to thickness of the front transparent electrode 104. Thus, optical efficiency of the thin film silicon solar cell may be reduced. Therefore, a color calibration thin film may be further provided into the thin film silicon solar cell to prevent the optical efficiency from being reduced. (This will be described in detail with reference to FIGS. 5 and 6)

FIGS. 5 and 6 are cross-sectional views of a thin film silicon solar cell according to another embodiment of the present invention.

Referring to FIG. 5, a thin film silicon solar cell 500 includes a light absorbing layer 312. A front transparent electrode 304 and a front substrate 302 may be successively disposed on one surface of the light absorbing layer 312. A rear transparent electrode 324 and a rear substrate 322 may be successively disposed on the other surface of the light absorbing layer 312. A first color calibration thin film 303 may be disposed between the front substrate 302 and the front transparent electrode 304.

The front substrate 302 and the rear substrate 322 may be transparent glass substrates, respectively.

Each of the front substrate 302 and the rear substrate 322 may have a refractive index of about 1.5. First light 400 may be incident into the front substrate 302, and second light 420 may be incident into the rear substrate 322. The first light 400 may be solar light. The second light 420 may be light different from the solar light.

The front substrate 302 and the rear substrate 322 may be formed of transparent conductive materials, respectively. The front substrate 302 and the rear substrate 322 may be formed of, for example, one of ITO, ZnO:Al, ZnO:Ga, and SnO₂:F. Each of the front substrate 302 and the rear substrate 322 may have a refractive index of about 1.5 to about 2.0. Each of the front substrate 302 and the rear substrate 322 may have a thickness of about 50 nm to about 1,500 nm.

The first color calibration thin film 303 disposed between the front substrate 302 and the front transparent electrode 304 may be a single layer or/and a multilayer. The first color calibration thin film 303 may be formed of a material transmitting visible light. The material transmitting the visible light may be an insulation material having a refractive index of about 1.4 to about 2.5. The insulation material may be one of Al₂O₃, TiO₂, AlTiO, and HfO₂. The first color calibration thin film 303 may be formed of a material different from that of the front substrate 302. The first color calibration thin film 303 may have a thickness of about 10 nm to about 1,000 nm.

The light absorbing layer 312 may be a single layer and/or a multilayer. The light absorbing layer 312 may include an amorphous silicon layer, an amorphous silicon germanium layer, a micro crystalline silicon layer, or a micro crystalline silicon germanium layer. The light absorbing layer 312 may have a refractive index of about 3.5. As shown in FIG. 1, the light absorbing layer 312 may include a first conductive layer 312a and a second conductive layer 312b.

The first light 400 incident into the front substrate 302 may transmit the front substrate 302 to transmit the first color calibration thin film 303. Also, a portion of the first light 400 may be reflected by an interface between the front substrate 302 and the first color calibration thin film 303. The reflected first light 400 may be reflected by a refractive index difference between the front substrate 302 and the first color calibration thin film 303. The reflected first light 400 may vary by a refractive index and thickness of the first color calibration thin film 303.

The first light transmitting the first calibration thin film 303 may transmit the front transparent electrode 304. Also, a portion of the first light 400 may be reflected by an interface between the first color calibration thin film 303 and the front transparent electrode 304. The reflected first light 400 may be reflected by a refractive index difference between the first color calibration thin film 303 and the front transparent electrode 304. The reflected first light 400 may vary by a refractive index and thickness of the first color calibration thin film 303, and a thickness of the front transparent electrode 304.

The first light 400 transmitting the front transparent electrode 304 may be absorbed into the light absorbing layer 312 and reflected by an interface between the front transparent electrode 304 and the light absorbing layer 312. The first light 400 may be reflected by a refractive index difference between the front transparent electrode 304 and the light absorbing layer 312. The reflected first light 400 may vary in color according to a change of thickness of the front transparent electrode 304. The first light 400 absorbed into the light absorbing layer 312 may generate carriers (for example, electrons or holes). Thus, a current between the first conductive layer 312a and the second conductive layer 312b may be generated.

As described above, since the first color calibration thin film 303 is disposed between the front substrate 302 and the front transparent electrode 304, a portion of the first light 400 may be reflected by the interface between the front substrate 302 and the first color calibration thin film 303, the interface between the first color calibration thin film 303 and the front transparent electrode 304, and the interface between the front transparent electrode 304 and the light absorbing layer 312. The first light 400 reflected by the interfaces may have wavelength bands different from each other. Thus, since the first color calibration thin film 303 may be further provided, the reflected light may vary in wavelength band, as well as, the number of wavelength bands of the reflected light may be increased, when compared with a solar cell in which first color calibration thin film 303 is not provided. Thus, the wavelength bands of the reflected first light 400 may be mixed with each other to emit various colors through a front surface of the thin film silicon solar cell 500.

In case of the solar cell in which the first color calibration thin film 303 is not provided, various color may be embodied according to a thickness of a transparent electrode. However, since an amount of light absorbed into a light absorbing layer may vary according to the thickness of the transparent electrode, optical efficiency of the solar cell may be reduced. In this case, the first color calibration thin film 303 may be further provided into the solar cell to prevent the optical efficiency from being reduced. For example, in case where the more the transparent electrode is increased in thickness, the more the optical efficiency of the solar cell is reduced, the first color calibration thin film 303 may be further provided into the solar cell to fix a thickness of the transparent electrode. Then, the first calibration thin film 303 may be adjusted in refractive index and thickness to embody various colors without varying in optical efficiency of the solar cell.

The second light 420 incident into the rear substrate 322 may be reflected by an interface between the rear transparent electrode 324 and the light absorbing layer 312. The reflected second light 420 may be different in color according to a thickness of the rear transparent electrode 324. Thus, a rear surface of the thin film silicon solar cell 500 may be embodied by the reflected second light 420.

Referring to FIG. 6, a thin film silicon solar cell 600 may further include a second color calibration thin film 333 between the rear substrate 322 and the rear transparent electrode 324. The second light 420 incident into the rear substrate 322 may be reflected by an interface between the front substrate 322 and the second color calibration thin film 323, an interface between the second color calibration thin film 333 and the rear transparent electrode 324, and an interface between the rear transparent electrode 324 and the light absorbing layer 312. The second light 420 by the interfaces may have wavelength bands different from each other. The wavelength bands of the reflected second light 420 may be mixed with each other to embody a color of a rear surface of the thin film silicon solar cell 600.

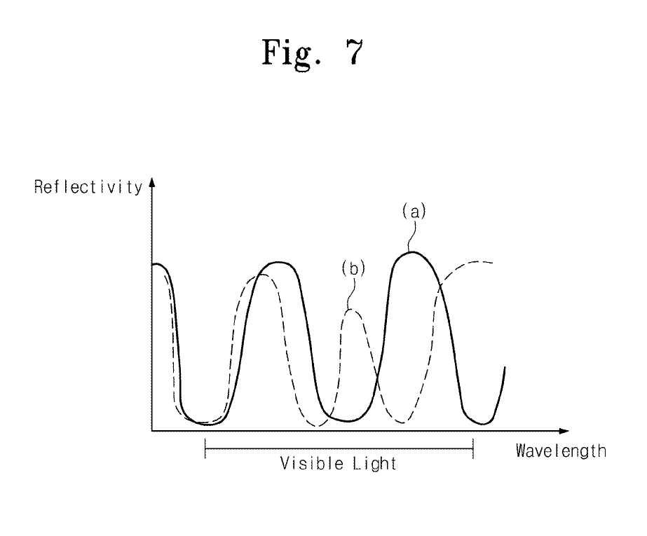

FIG. 7 is a graph illustrating reflectivity depending on whether a color calibration thin film exists in the thin film silicon solar cell according to another embodiment of the present invention.

Referring to FIG. 7, a solid line (a) illustrates a reflectance curve of a general thin film silicon solar cell, and a dot line (b) illustrates a reflectance curve of a thin film silicon solar cell including a color calibration thin film. Comparing the solid line (a) with the dot line (b), it is seen that the solid line (a) has a width greater than that of the dot line (b). Also, the number of wavelengths having maximum reflectivity in the dot line (b) within a visible light wavelength band is greater than that of wavelengths having maximum reflectivity in the solid line (a). Thus, since the wavelengths having maximum reflectivity may be mixed with each other to embody a color of the thin film silicon solar cell, it is unnecessary to add a color calibration thin film to vary in color.

Also, the thin film silicon solar cell including the color calibration thin film may vary in color according to a thickness of the color calibration thin film. The more the color calibration thin film is increased in thickness, the more a width between the reflectance curves expressed as the dot line (b) is reduced. Thus, the reflected light may vary in wavelength band.

The thin film silicon solar cell according to the present invention may be adjusted in thicknesses of the front transparent electrode and the rear transparent electrode to independently embody colors on the front transparent electrode and the rear transparent electrode. Thus, the front and rear transparent electrodes may have the same color or colors different from each other. Also, since various colors may be embodied according to thicknesses of the transparent electrodes, it may be unnecessary to provide a separate color filter. Thus, manufacturing costs may be reduced.

The thin film silicon solar cell according to the present invention may embody various colors by changing the thickness of the front transparent electrode. However, the optical efficiency of the solar cell may be reduced according to the thickness of the front transparent electrode. Thus, the first color calibration thin film may be further provided between the front substrate and the front transparent electrode to embody various colors. In addition, it may prevent the optical efficiency of the thin film silicon solar cell may be reduced.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A thin film silicon solar cell comprising:
a light absorbing layer;
a front transparent electrode disposed on one surface of the light absorbing layer to emit light having a first color; and
a rear transparent electrode disposed on the other surface of the light absorbing layer to emit light having a second color.

2. The thin film silicon solar cell of claim 1, wherein the light absorbing layer, the front transparent electrode, and the rear transparent electrode have refractive indexes different from each other.

3. The thin film silicon solar cell of claim 1, wherein the front transparent electrode and the rear transparent electrode have the same thickness.

4. The thin film silicon solar cell of claim 1, wherein the front transparent electrode has a thickness greater than that of the rear transparent electrode.

5. The thin film silicon solar cell of claim 1, wherein the front transparent electrode has a thickness less than that of the rear transparent electrode.

6. The thin film silicon solar cell of claim 1, wherein each of the front transparent electrode and the rear transparent electrode has a thickness of about 50 nm to about 1,500 nm.

7. The thin film silicon solar cell of claim 1, wherein each of the front transparent electrode and the rear transparent electrode is formed of one of ITO, ZnO:Al, ZnO:Ga, and SnO₂:F.

8. The thin film silicon solar cell of claim 1, wherein the light absorbing layer comprises one of an amorphous silicon layer, an amorphous silicon germanium layer, a micro crystalline silicon layer, and a micro crystalline silicon germanium layer.

9. A thin film silicon solar cell comprising:
a light absorbing layer;
a front transparent electrode disposed on one surface of the light absorbing layer to emit light having a first color;
a rear transparent electrode disposed on the other surface of the light absorbing layer to emit light having a second color
a front substrate disposed on the front transparent electrode, the front substrate being spaced apart from the light absorbing layer;
a rear substrate disposed on the rear transparent electrode, the rear substrate being spaced apart from the light absorbing layer; and
a first color calibration thin film disposed between the front substrate and the front transparent electrode.

10. The thin film silicon solar cell of claim 9, further comprising a second color calibration thin film between the rear substrate and the rear transparent electrode.

11. The thin film silicon solar cell of claim 9, wherein each of the front substrate and the rear substrate comprises a transparent substrate.

12. The thin film silicon solar cell of claim 9, wherein the first color calibration thin film has a thickness of about 100 nm to about 1,000 nm.

13. The thin film silicon solar cell of claim 9, wherein the first color calibration thin film is formed of an insulation material having a refractive index of about 1.4 to about 2.5.

14. The thin film silicon solar cell of claim 13, wherein the insulation material comprises one of Al₂O₃, TiO₂, AlTiO, and HfO₂.
